(19) United States
(12) Patent Application Publication
(10) Pub. No.: US 2010/0102338 A1
(43) Pub. Date: Apr. 29, 2010

(54) III-Nitride Semiconductor Light Emitting Device

(75) Inventors: Chang Tae Kim, Seongnam-si (KR); Min Gyu Na, Gimje-si (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/647,731

(22) Filed: Dec. 28, 2009

Related U.S. Application Data
(63) Continuation of application No. PCT/KR2009/005710, filed on Oct. 7, 2009.

(30) Foreign Application Priority Data
Oct. 24, 2008 (KR) 10-2008-0104567

(51) Int. Cl. H01L 33/00

(52) U.S. Cl. 257/94; 257/98; 257/E33.023; 257/E33.074

(57) ABSTRACT

The present disclosure relates to a III-nitride semiconductor light-emitting device including a substrate, a plurality of III-nitride semiconductor layers including a first nitride semiconductor layer formed over the substrate and having a first conductivity type, a second nitride semiconductor layer formed over the first nitride semiconductor layer and having a second conductivity type different from the first conductivity type, and an active layer disposed between the first nitride semiconductor layer and the second nitride semiconductor layer and generating light by recombination of electrons and holes, and an opening formed along the plurality of III-nitride semiconductor layers from the substrate, and including a first scattering surface scattering the light generated in the active layer and a second scattering surface having a different slope from that of the first scattering surface.

### CROSS-REFERENCE TO RELATED APPLICATIONS

This application is a continuation of PCT Application No. PCT/KR2009/005710 filed on Oct. 7, 2009, which claims the benefit and priority to Korean Patent Application No. 10-2008-0104567, filed Oct. 24, 2008. The entire disclosures of the applications identified in this paragraph are incorporated herein by reference.

### FIELD

The present disclosure relates generally to a III-nitride semiconductor light-emitting device, and more particularly, to a III-nitride semiconductor light-emitting device which can improve external light extraction efficiency. The III-nitride semiconductor light-emitting device means a light-emitting device such as a light-emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view of an example of a conventional III-nitride semiconductor light-emitting device. The III-nitride semiconductor light-emitting device includes a substrate 100, a buffer layer 200 grown on the substrate 100, an n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, an n-side electrode 800 formed on the n-type nitride semiconductor layer 300 exposed by mesa-etching the p-type nitride semiconductor layer 500 and the active layer 400, and an optional protection film 900.

In the case of the substrate 100, a GaN substrate can be used as a homo-substrate. A sapphire substrate, a SiC substrate or a Si substrate can be used as a hetero-substrate. However, any type of substrate that can have a nitride semiconductor layer grown thereon can be employed. In the case that the SiC substrate is used, the n-side electrode 800 can be formed on the surface of the SiC substrate.

The nitride semiconductor layers epitaxially grown on the substrate 100 are usually grown by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 describes a technique of growing an AlN buffer layer with a thickness of 100 to 500 Å on a sapphire substrate at 380 to 800° C. In addition, U.S. Pat. No. 5,290,393 describes a technique of growing an Al₍ₓ₎Ga₍₁₋ₓ₎N (0≦x<1) buffer layer with a thickness of 10 to 5000 Å on a sapphire substrate at 200 to 900° C. Moreover, U.S. Publication No. 2006/154454 describes a technique of growing a SiC buffer layer (seed layer) at 600 to 990° C., and growing an In₍ₓ₎Ga₍₁₋ₓ₎N (0<x≦1) thereon. In particular, it is provided with an undoped GaN layer with a thickness of 1 micron to several microns (μm) on the AlN buffer layer, the Al₍ₓ₎Ga₍₁₋ₓ₎N (0≦x<1) buffer layer or the SiC/In₍ₓ₎Ga₍₁₋ₓ₎N (0<x≦1) layer.

In the n-type nitride semiconductor layer 300, at least the n-side electrode 800 formed region (n-type contact layer) is doped with a dopant. In some embodiments, the n-type contact layer is made of GaN and doped with Si. U.S. Pat. No. 5,733,796 describes a technique of doping an n-type contact layer at a target doping concentration by adjusting the mixture ratio of Si and other source materials.

The active layer 400 generates light quanta by recombination of electrons and holes. For example, the active layer 400 contains In₍ₓ₎Ga₍₁₋ₓ₎N (0<x≦1) and has a single layer or multi-quantum well layers.

The p-type nitride semiconductor layer 500 is doped with an appropriate dopant such as Mg, and has p-type conductivity by an activation process. U.S. Pat. No. 5,247,533 describes a technique of activating a p-type nitride semiconductor layer by electron beam irradiation. Moreover, U.S. Pat. No. 5,306,662 describes a technique of activating a p-type nitride semiconductor layer by annealing over 400° C. U.S. Publication No. 2006/157714 describes a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type nitride semiconductor layer 500. U.S. Pat. No. 5,563,422 discloses a technique associated with a light transmitting electrode composed of Ni and Au formed over almost the entire surface of the p-type nitride semiconductor layer 500 and in ohmic-contact with the p-type nitride semiconductor layer 500. In addition, U.S. Pat. No. 6,515,306 describes a technique of forming an n-type superlattice layer on a p-type nitride semiconductor layer, and forming a light-transmitting electrode made of indium tin oxide (ITO) thereon.

The p-side electrode 600 can be formed so thick as to not transmit but rather to reflect light toward the substrate 100. This technique is called a flip chip technique. U.S. Pat. No. 6,194,743 describes a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire-bonding. U.S. Pat. No. 5,563,422 describes a technique of forming an n-side electrode with Ti and Al.

The optional protection film 900 can be made of SiO₂.

The n-type nitride semiconductor layer 300 or the p-type nitride semiconductor layer 500 can be constructed as a single layer or as plural layers. Vertical light-emitting devices are introduced by separating the substrate 100 from the nitride semiconductor layers using a laser technique or wet etching.

FIGS. 2 and 3 are views of examples of light-emitting devices described in U.S. Pat. Publication No. 2006/0192247. FIG. 2 illustrates a state where light generated on the inside of the light-emitting device A is not emitted to the outside of the light-emitting device but vanished, and FIG. 3 illustrates a state where inclined surfaces 120 are formed on the surfaces of the light-emitting device such that light generated on the inside of the light-emitting device A is emitted to the outside of the light-emitting device.

FIG. 4 is a view of an example of a light-emitting device described in Japanese Pat. Publication No. 2001-24222. The light-emitting device includes trenches 920 formed from a p-side electrode 600 to an n-type nitride semiconductor layer 300. Therefore, light generated on the inside of the light-emitting device can be easily emitted to the outside of the light-emitting device.

However, the conventional light-emitting devices described in, for example, U.S. Patent Publication No. 2006/0192247 or Japanese Patent Publication No. 2001-24222 have the disadvantage that light generated on the inside A of the light-emitting device or the active layer 400 and incident on the substrate 100 is reflected and, thus, not extracted to the outside of the light-emitting device.

### SUMMARY

This section provides a general summary of the disclosure, and is not a comprehensive disclosure of its full scope or all of its features.

There is provided a III-nitride semiconductor light-emitting device including: a substrate; a plurality of III-nitride semiconductor layers including a first nitride semiconductor layer formed over the substrate and having a first conductivity type, a second nitride semiconductor layer formed over the first nitride semiconductor layer and having a second conductivity type different from the first conductivity type, and an active layer disposed between the first nitride semiconductor layer and the second nitride semiconductor layer and generating light by recombination of electrons and holes; and an opening formed along the plurality of III-nitride semiconductor layers from the substrate, and including a first scattering surface scattering the light generated in the active layer and a second scattering surface having a different slope from that of the first scattering surface.

According to a III-nitride semiconductor light-emitting device of the present disclosure, light extraction efficiency of the light emitting device can be improved.

In an embodiment, according to a III-nitride semiconductor light emitting device of the present disclosure, extraction efficiency of the light incident on the substrate of the light emitting device is improved.

In another embodiment, according to a III-nitride semiconductor light emitting device of the present disclosure, light extraction efficiency of the nitride semiconductor layers of the III-nitride semiconductor light emitting device is improved.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view of an example of a conventional III-nitride semiconductor light-emitting device.

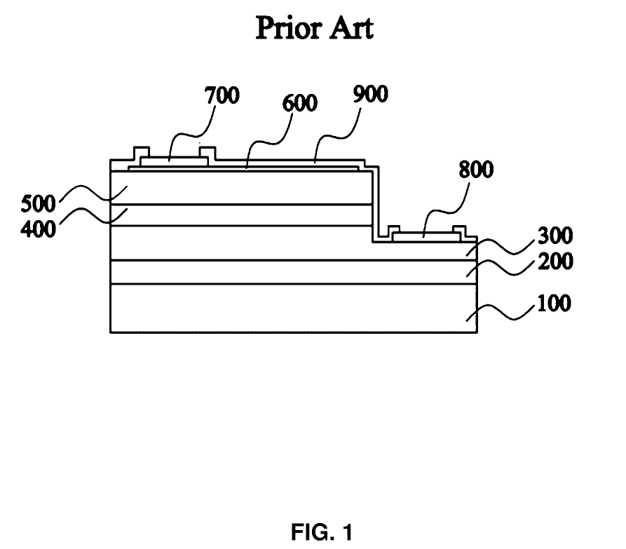

FIG. 2 is a view of one example of a light-emitting device described in U.S. Pat. Publication No. 2006/0192247.

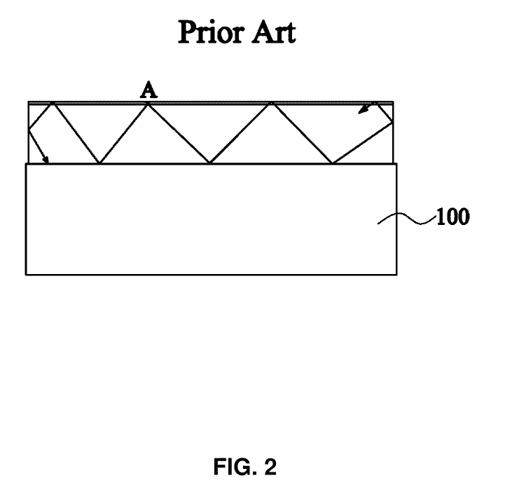

FIG. 3 is a view of another example of the light-emitting device described in U.S. Pat. Publication No. 2006/0192247.

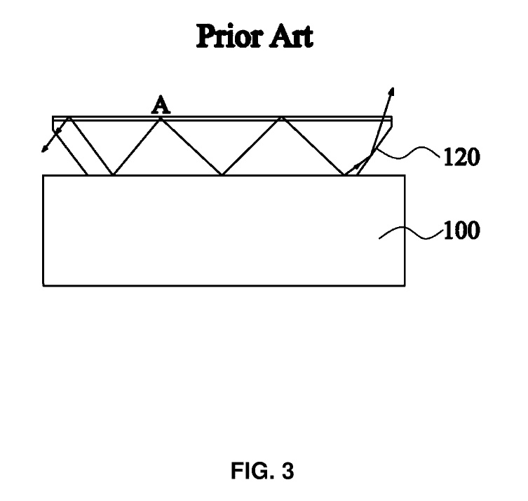

FIG. 4 is a view of an example of a light-emitting device described in Japanese Pat. Publication No. 2001/24222.

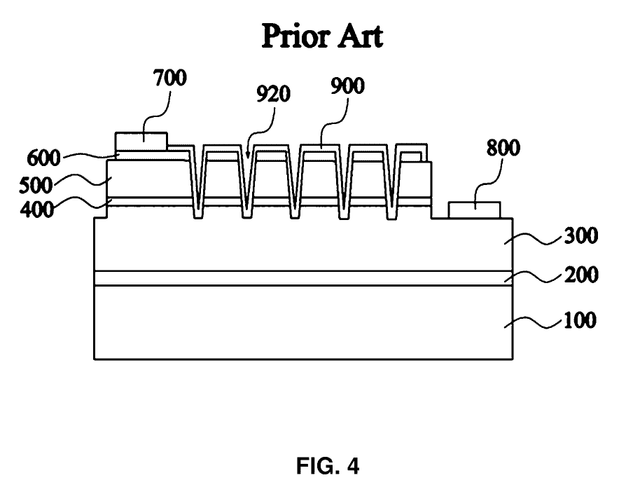

FIG. 5 is a view of one embodiment of a III-nitride semiconductor light-emitting device according to the present disclosure.

FIG. 6 is a view of another embodiment of the III-nitride semiconductor light-emitting device according to the present disclosure.

FIG. 7 is a view of an embodiment of a method for fabricating a III-nitride semiconductor light-emitting device according to the present disclosure.

FIG. 8 is a view of various shapes of patterns according to the present disclosure.

FIG. 9 is an image of an example of an opening formed in the III-nitride semiconductor light-emitting device according to the present disclosure.

FIG. 10 is an image of the embodiment of the III-nitride semiconductor light-emitting device according to the present disclosure.

FIG. 11 is an enlarged image of the light-emitting device of FIG. 10.

Corresponding reference numerals indicate corresponding parts throughout the several views of the drawings.

### DETAILED DESCRIPTION

Hereinafter, the present disclosure will now be described in detail with reference to the accompanying drawings.

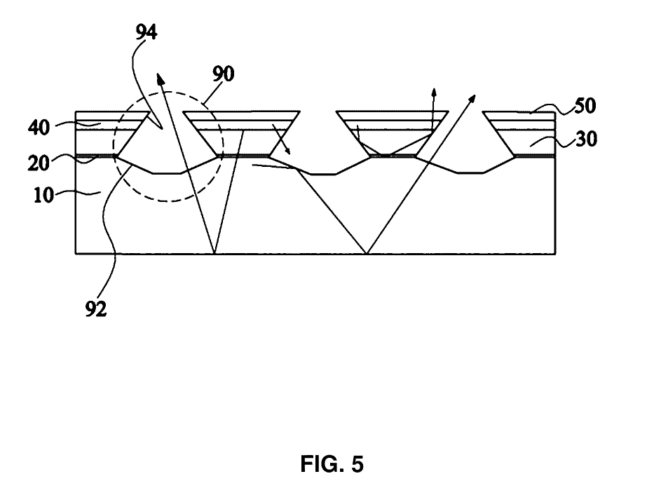

FIG. 5 is a view of one embodiment of a III-nitride semiconductor light-emitting device according to the present disclosure. The III-nitride semiconductor light-emitting device includes a substrate 10, a buffer layer 20 formed on the substrate 10, an n-type nitride semiconductor layer 30 grown on the buffer layer 20, an active layer 40 grown on the n-type nitride semiconductor layer 30 and generating light by recombination of electrons and holes, a p-type nitride semiconductor layer 50 grown on the active layer 40, and an opening 90.

The opening 90 is formed along the buffer layer 20, the n-type nitride semiconductor layer 30, the active layer 40, and the p-type nitride semiconductor layer 50 from the substrate 10. The opening 90 includes a scattering surface 92 and a scattering surface 94. The scattering surface 92 is formed on the substrate 10. The scattering surface 94 is formed along the buffer layer 20, the n-type nitride semiconductor layer 30, the active layer 40, and the p-type nitride semiconductor layer 50.

The scattering surface 92 is generally in the shape of a saucer when the substrate 10 is slightly caved in and can scatter the light generated in the active layer 40 and incident on the substrate 10. The scattering surface 94 is narrowed along the buffer layer 20, the n-type nitride semiconductor layer 30, the active layer 40, and the p-type nitride semiconductor layer 50 from the substrate 10, and can scatter the light generated in the active layer 40. The opening 90 may include the scattering surfaces 92 and 94 together or apart. However, when the opening 90 includes the scattering surfaces 92 and 94 together, the light generated in the active layer 40 is emitted to the outside of the light-emitting device (hereinafter referred to as “light extraction efficiency”).

In some embodiments, the light-emitting device includes the plurality of opening 90 in order to improve light extraction efficiency.

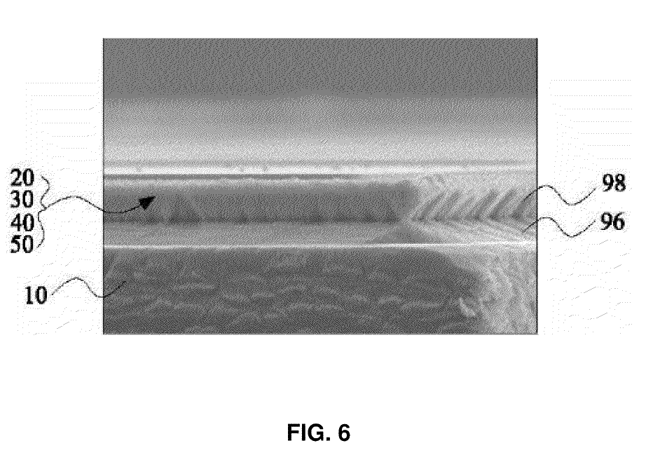

FIG. 6 is a view of another embodiment of the III-nitride semiconductor light-emitting device according to the present disclosure. The III-nitride semiconductor light-emitting device includes a scattering surface 96 and a scattering surface 98 which are formed on its surfaces.

The scattering surface 96 is formed on the substrate 10, and the scattering surface 98 is formed along a buffer layer 20, an n-type nitride semiconductor layer 30, an active layer 40, and a p-type nitride semiconductor layer 50. The scattering surface 96 and the scattering surface 98 are generally wedge-shaped. The light-emitting device may include the scattering surfaces 96 and 98 together or apart. In some embodiments, the light-emitting device includes the scattering surfaces 96 and 98 together in order to improve light extraction efficiency.

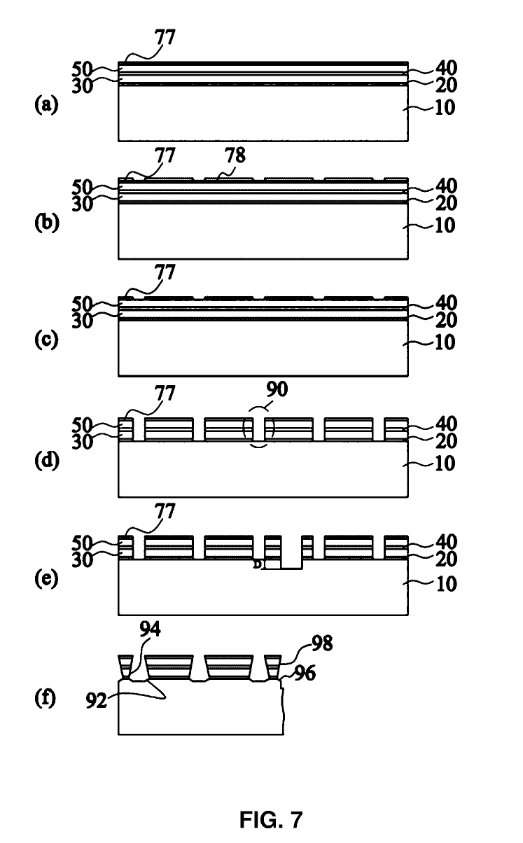

Hereinafter, a method for fabricating a III-nitride semiconductor light-emitting device according to the present disclosure will now be described in detail. FIG. 7 is a view of an embodiment of the method for fabricating the III-nitride semiconductor light-emitting device according to the present disclosure.

A substrate 10 is prepared, and then nitride semiconductor layers 20, 30, 40, and 50 are grown on the substrate 10. Next, a protection film 77 is formed on the nitride semiconductor layers 20, 30, 40, and 50. The protection film 77 may be made of SiO₂, etc. (referring to FIG. 7(a)). According to the present disclosure, the substrate 10 may be a sapphire substrate.

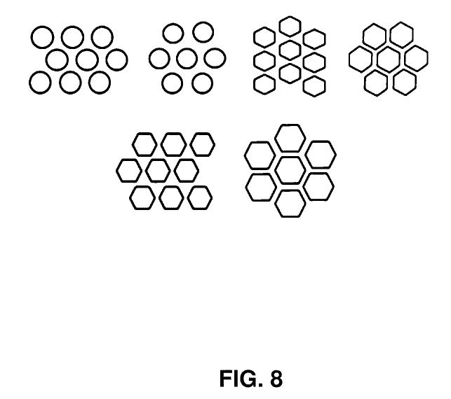

Patterns 78 are formed on the protection film 77 (referring to FIG. 7(b)). FIG. 8 illustrates various shapes of the patterns 78 which can be used in the present disclosure, such as circles or hexagons.

The substrate 10 with the patterns 78 formed thereon is immersed into a buffered oxide etchant (BOE) solution such that the protection film 77 is etched and removed according to the patterns 78 (referring to FIG. 7(c)).

The nitride semiconductor layers 20, 30, 40, and 50 are dry etched according to the patterns 78 until the substrate 10 is exposed. Here, opening 90 are formed. The dry etching may be performed using an inductively coupled plasma (ICP) and so on (referring to FIG. 7(d)).

The substrate 10 and the nitride semiconductor layers 20, 30, 40, and 50 are divided into individual light-emitting devices. Such division can be performed using a laser scribing process. In some embodiments, the depth D of a cutting surface formed by the laser scribing process ranges from 0.5 μm to 30 μm from the surface of the substrate 10. Accordingly, the entire light-emitting device can be easily divided into the individual light-emitting devices by a physical force. If the depth D of the cutting surface is below 0.5 μm, while the entire light-emitting device is physically divided into the individual light-emitting devices, cracks may occur on and in the light-emitting devices or electrical characteristics may be degraded. If the depth D of the cutting surface is over 30 μm, while the individual light-emitting devices are fabricated, they may be easily broken, resulting in low productivity (referring to FIG. 7(e)).

The light-emitting device is wet etched. For example, when the substrate 10 is a plane substrate, the light-emitting device may be immersed into a mixture of H₂SO₄ and H₃PO₄ (3:1) at 280° C. for 13 min. During this process, scattering surfaces 92 and 94 are formed on the opening 90 and scattering surfaces 96 and 98 are formed on the side surfaces of the light-emitting device due to etch rate differences between the substrate 10 and the buffer layer 20, the n-type nitride semiconductor layer 30, the active layer 40 and the p-type nitride semiconductor layer 50. In some embodiments, the roughness of the scattering surfaces 92, 94, 96, and 98 is maintained below a few tens of nanometers. If their roughness is over a few tens of nanometers, the scattering surfaces 92, 94, 96, and 98 may reduce light extraction efficiency of the light-emitting device by acting as residual impurity (referring to FIG. 7(f)).

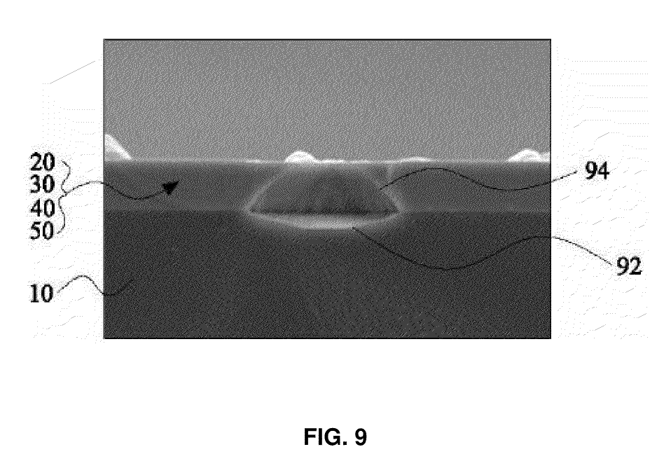

FIG. 9 is an image of an example of the opening 90 formed in the III-nitride semiconductor light-emitting device according to the present disclosure. The scattering surface 92 is formed on the substrate 10, and the scattering surface 94 is formed along the nitride semiconductor layers 20, 30, 40, and 50.

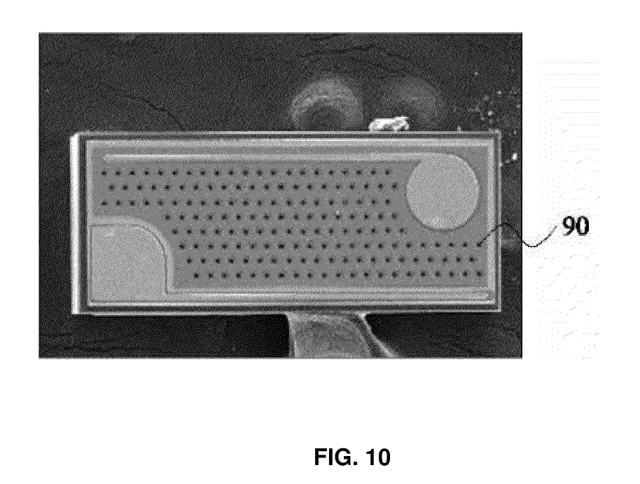

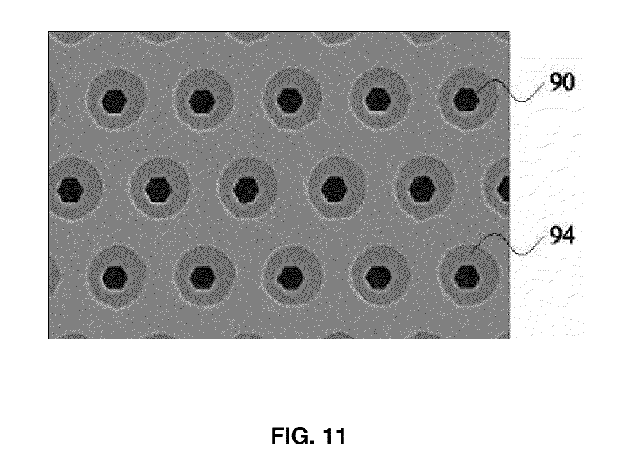

FIG. 10 is an image of the embodiment of the III-nitride semiconductor light-emitting device according to the present disclosure, and FIG. 11 is an enlarged image of the light-emitting device of FIG. 10. The opening 90 are formed in the III-nitride semiconductor light-emitting device. To form the opening 90, hexagonal patterns having one side length of 4 μm are formed at intervals of 12 μm.

Hereinafter, variety examples of the present invention are explained.

(1) The III-nitride semiconductor light-emitting device wherein the first scattering surface is formed on the substrate.

(2) The III-nitride semiconductor light-emitting device wherein the first scattering surface is formed when the substrate is caved in.

(3) The III-nitride semiconductor light-emitting device wherein the second scattering surface is formed along the plurality of III-nitride semiconductor layers.

(4) The III-nitride semiconductor light-emitting device wherein the second scattering surface has an opening which is narrowed along the plurality of III-nitride semiconductor layers from the substrate.

(5) The III-nitride semiconductor light-emitting device wherein opening is formed plurality.

(6) The III-nitride semiconductor light-emitting device wherein the first scattering surface and the second scattering surface are formed by wet etching.

(7) The III-nitride semiconductor light-emitting device wherein the first scattering surface is formed when the substrate is caved in, and the second scattering surface is narrowed along the plurality of III-nitride semiconductor layers from the substrate.

(8) The III-nitride semiconductor light-emitting device comprising a wedge-shaped scattering surface on a surface thereof.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A III-nitride semiconductor light-emitting device, comprising:
a substrate;
a plurality of III-nitride semiconductor layers including a first nitride semiconductor layer formed over the substrate and having a first conductivity type, a second nitride semiconductor layer formed over the first nitride semiconductor layer and having a second conductivity type different from the first conductivity type, and an active layer disposed between the first nitride semiconductor layer and the second nitride semiconductor layer and generating light by recombination of electrons and holes; and
an opening formed along the plurality of III-nitride semiconductor layers from the substrate, and including a first scattering surface scattering the light generated in the active layer and a second scattering surface having a different slope from that of the first scattering surface.

2. The III-nitride semiconductor light-emitting device of claim 1, wherein the first scattering surface is formed on the substrate.

3. The III-nitride semiconductor light-emitting device of claim 2, wherein the first scattering surface is formed as a concave portion of the substrate.

4. The III-nitride semiconductor light-emitting device of claim 1, wherein the second scattering surface is formed along the plurality of III-nitride semiconductor layers.

5. The III-nitride semiconductor light-emitting device of claim 4, wherein the second scattering surface has an opening which is narrowed along the plurality of III-nitride semiconductor layers from the substrate.

6. The III-nitride semiconductor light-emitting device of claim 1, wherein the first scattering surface is formed when the substrate is caved in, and the second scattering surface is narrowed along the plurality of III-nitride semiconductor layers from the substrate.

7. The III-nitride semiconductor light-emitting device of claim 6, comprising a wedge-shaped scattering surface on a surface thereof.
